(19) United States
(12) Patent Application Publication
(10) Pub. No.: US 2006/0006394 A1
(43) Pub. Date: Jan. 12, 2006

(54) Silicon carbide Schottky diodes and fabrication method

(75) Inventor: Olof Claes Erik Kordina, Pittsburgh, PA (US)

Correspondence Address: SCHNADER HARRISON SEGAL & LEWIS, LLP, 1600 MARKET STREET, SUITE 3600, PHILADELPHIA, PA, 19103, US

(73) Assignee: CARACAL, INC., FORD CITY, PA (US)

(21) Appl. No.: 11/139,955

(22) Filed: May 27, 2005

Related U.S. Application Data
(60) Provisional application No. 60/575,332, filed on May 28, 2004.

(51) Int. Cl. H01L 29/15

(52) U.S. Cl. 257/77

(57) ABSTRACT

A semiconductor device and method of formation wherein a disjointed termination layer 102 is formed around a Schottky metal region 110. A SiC substrate 104 is provided, on top of which a SiC blocking layer 108 is disposed. The disjointed termination layer 102 is formed above the SiC blocking layer 108. The termination is preferably an epitaxial SiC layer. The Schottky metal region 110 is formed on the blocking layer 108, preferably on the C-face of the blocking layer.

This application is based on, and claims priority to, provisional application having Ser. No. 60/575,332, having a filing date of May 28, 2004, entitled C-face SiC Power Schottky Diodes with Disjointed p-Epitaxial termination.

### FIELD OF THE INVENTION

The field of invention is diodes and other semiconductor devices having SiC substrates, and more particularly power Schottky Diodes/Rectifiers in silicon carbide (SiC).

### BACKGROUND OF THE INVENTION

High voltage SiC Schottky diodes, which can handle voltages between 300 V and 3.5 kV, are expected to compete with silicon p-doped-intrinsic-n-doped (PIN) diodes fabricated of similar voltage ratings. Such diodes may handle up to 100 Amps of current, depending on their size. High voltage Schottky diodes have a number of applications, particularly in the field of power conditioning, distribution and control.

The basic conventional structure of a Schottky diode is shown in FIG. 1. Schottky diode 100 has an n-type SiC substrate 102 on which an n⁻ voltage blocking epilayer 104 which functions as a drift region is formed. A buffer layer 106 may be provided between substrate 102 and voltage blocking layer 104. The device includes a Schottky contact 108 formed directly on the n⁻ region 104. Surrounding the Schottky contact 108 is a p-type edge termination region 110 formed by ion implantation and a passivating layer 112. The implants may be aluminum, boron, or any other suitable p-type dopant. The purpose of the edge termination region is to prevent the electric field crowding at the edges, and to prevent the depletion region from interacting with the surface of the device. Surface effects may cause the depletion region to spread unevenly, which may adversely affect the breakdown voltage of the device. Other termination techniques include guard rings and floating field rings.

In addition, the back side of the device may be implanted with n-type dopants to lower the resistance of the back side ohmic contact. These implants must be annealed at a high temperature prior to deposition of the Schottky contact, which cannot be annealed.

An important advantage of a SiC Schottky diode in such applications is its switching speed. Silicon-based PIN devices exhibit relatively poor switching speeds. A silicon PIN diode may have a maximum switching speed of approximately 20 kHz, depending on its voltage rating. In contrast, silicon carbide-based devices are theoretically capable of much higher switching speeds, in excess of 100 times better than silicon. In addition, silicon carbide devices are capable of handling a higher current density than silicon devices.

Although there are significant advantages of SiC Schottky diodes, and other SiC devices, reliable fabrication of such devices is difficult. The two aspects that need particular attention in this respect are: (a) Optimally doped and substantially defect-free epitaxial layers for their voltage blocking layers; and (b) Edge termination designs that allow blocking of high voltages where the critical field is close to the theoretical maximum of the material.

### SUMMARY OF THE INVENTION

Unique SiC epitaxial layer methods and new edge termination designs for allowing high voltage operation are presented.

Embodiments of the invention provide a semiconductor device and method of formation wherein a disjointed termination layer is formed around a Schottky metal region. Preferably a SiC substrate is provided, on top of which a SiC blocking is disposed. The disjointed termination layer is formed above the SiC blocking layer. The termination is preferably an epitaxial SiC layer. The Schottky region is patterned on the blocking region and metal is deposited on the region. It has been found to be advantageous to form the Schottky metal region on the C-face of the blocking layer. The method is particularly applicable to Schottky diodes but can be implemented to form other semiconductor devices.

### DESCRIPTION OF THE DRAWINGS

The invention is best understood from the following detailed description when read with the accompanying drawings.

FIG. 1 depicts a prior art Schottky diode.

FIG. 2 depicts a Schottky diode according to an illustrative embodiment of the invention.

FIG. 3 depicts a plan view of a termination region according to an illustrative embodiment of the invention.

FIG. 4 depicts a plan view of a termination region according to a further illustrative embodiment of the invention.

FIG. 5 provides results of testing device at reverse bias.

FIG. 6 provides results of testing of diodes at forward bias.

FIGS. 7A-H depict a Schottky diode formation process according to an illustrative embodiment of the invention.

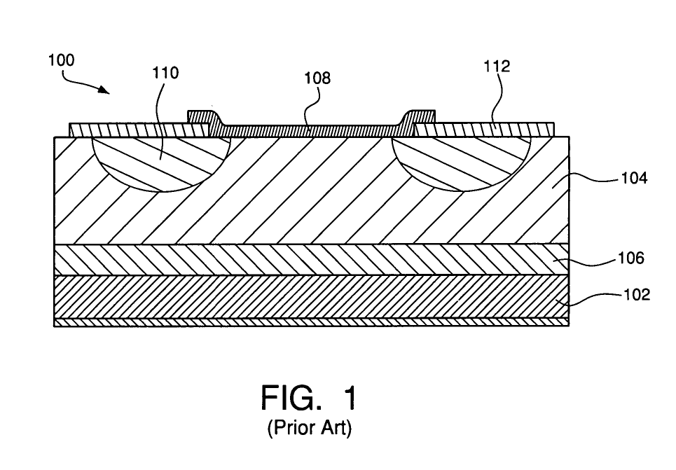

### DETAILED DESCRIPTION OF THE INVENTION

Embodiments of the invention provide Schottky diodes that utilize the C-face of 4H-SiC for the growth of epitaxial layers. As used herein “C-face” is not limited to the on-axis C-face but includes the off-axis C-face. The scope of the invention includes off-axis substrates to 90°. Illustrative off-axis amounts that may be suitable for particular applications include less than 60°, less than 30°, less than 8°, less than 4°, less than 2°, and less than 1°. In an exemplary embodiment of the invention, substrates are 8° off-axis toward the [11-20] direction or [1-100] direction, where the C-face is the [000-1] plane. The crystal structure of 4H-SiC is such that most wafers manufactured on its basal plane have two faces—a Si face with Si atoms, and another with C-face with mostly C atoms. Most of the devices made presently are on the Si-face because it is difficult to grow high quality epitaxial layers on C-face of SiC. However, there are many potential advantages of using the C-face of SiC for Schottky diode manufacture. First, the C-face is “flatter” in the sense that step bunching does not substantially exist as with the Si-face. Flatter surfaces result in reduced leakage of the diodes. Second, the incorporation of dopants is different, i.e. nitrogen (n-type) is easier to incorporate and Al (p-type) is more difficult which result in a better control of the doping, and quality of the drift layer since compensation effects of the p-type dopant is eliminated. There is a drawback with this namely, that Al-doping in excess of 10¹⁹ cm⁻3 is difficult to achieve on the C-face. This is, however, well within the levels needed for the present application. It is noted that other p-type dopants are within the spirit and scope of the invention.

(1) From a device processing standpoint, C-face offers a tremendous advantage over Si-face for the commercial manufacture of Schottky diode. This advantage primarily stems from the faster oxidation rate offered by C-face as compared to the Silicon face, making it much more suitable for adaptation to conventional silicon fabrication facilities. This may result in devices that are much cheaper, while offering better performance than those made using Si-face.

(2) From a device design and performance standpoint, C-face Schottky diodes can result in lower on-state voltage drop because of the different Schottky barrier heights offered by various Schottky metals. The on-state voltage drop of a Schottky diode depends on (a) The metal-semiconductor barrier height of the Schottky metal used; and (b) the resistance of the Schottky diode. The on-state voltage drop of a Schottky diode is directly proportional to the metal-semiconductor barrier height. However, the blocking capability (leakage current in blocking state) of a Schottky diode suffers exponentially with barrier height. On Si-face typical metal-semiconductor barrier heights for common metals are Tantalum (0.6 eV), Titanium (1.1 eV), Nickel (1.6 eV), Gold (1.9 eV). Although little research has been done to exactly determine these numbers for C-face, indications are that on C-face, metal-semiconductor barrier heights of common metals are about 0.2 eV higher than those on Si-face. In case of Si-face SiC Schottky diodes, Tantalum (0.6 eV) has not been found to be practical because of very large leakage currents observed in such diodes. Titanium (1.1 eV) results in higher on-state drop than Si PIN diodes, making them somewhat un-competitive. Hence, the ideal barrier height seems to be in the 0.7-0.9 eV range, which is where Tantalum is expected to be in case of C-face SiC Schottky diodes.

(3) The resistance of a Schottky diode has three components, namely: n− drift resistance, n+ substrate resistance, and backside contact resistance. The n− drift resistance is unavoidable as a practical matter; as its doping and thickness, and therefore the resistance, of the region must be sufficient to accommodate high voltages. The backside implants are annealed to help reduce backside contact resistance, which may become significant for low voltage applications.

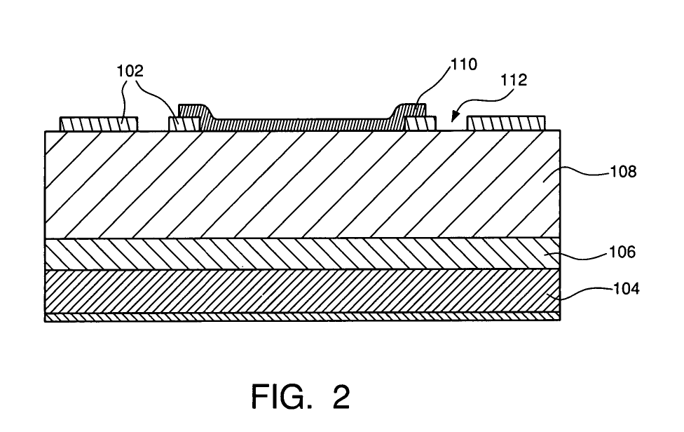

FIG. 2 depicts another embodiment of the invention according to an illustrative embodiment which includes the utilization of an preferably epitaxially-created highly doped, disjointed p-epitaxial layer 102 as an edge termination region, as opposed to an ion implanted edge termination. Substrate 104 is provided on which a buffer layer 106 may be disposed. A blocking layer 108 is formed on buffer layer 106. The disjointed termination layer 102 is formed on blocking layer 108 and patterned to provide the desired gap 112 in the termination region and a Schottky metal region 110. A Schottky metal is then formed in the desired region.

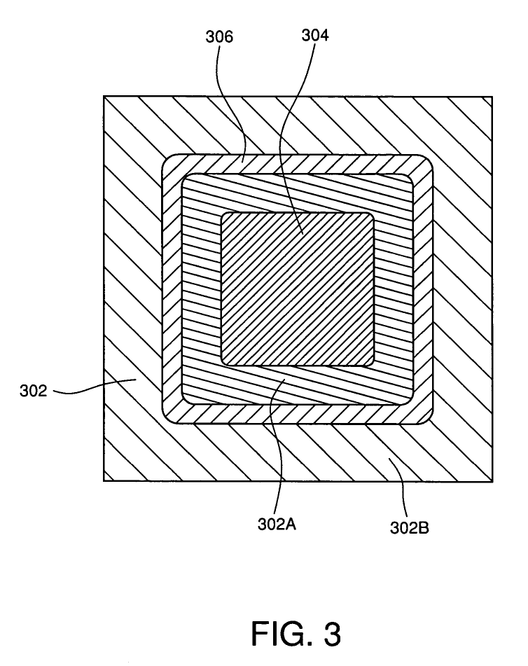

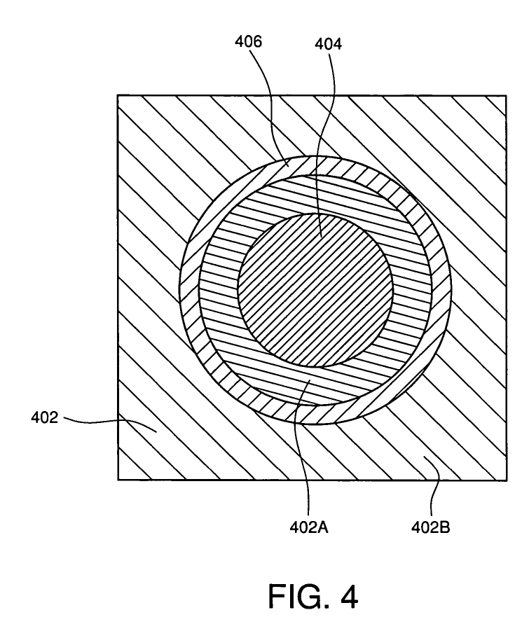

FIGS. 3 and 4 depict plan views of disjointed termination regions according to illustrative embodiments of the invention. FIG. 3 depicts a square device and FIG. 4 shows a round device. Termination regions 302, 402 surround Schottky regions 304 and 404, respectively, and include sections 302A, 302B, 402A and 402B. The “A” and “B” sections of each termination region are divided by a gap or disjointed region 306, 406. Illustrative dimensions for a circular device include a 50 μm Schottky region 404, and a termination region having a 15 μm wide termination ring 402A (80 μm outer diameter) surrounded by a 15 μm wide gap 406 and finally a 20 μm wide termination ring 402B. Various Schottky region diameters may be used, with suitably adjusted termination region sizes. Additional illustrative Schottky region diameters include 100 μm, 100 μm, 250 μm and 500 μm.

Since ion implantation results in damage to the edge termination part of the SiC crystal that severely affects the leakage currents of high voltage devices, epitaxially-created edge termination regions may result in higher yielding, lower leakage current high voltage Schottky diodes.

This differs from junction termination extension (JTE), because it utilizes higher doped p-epitaxial layers than optimally doped JTE layers. (Optimum JTE charge is defined as Epsilon*Critical Electric Field)/Electronic Charge Illustrative doping levels for the termination layer include: greater than about 1×10¹⁷ cm⁻³; about 1×10¹⁷ cm⁻³ to about 1×10²⁰ cm⁻³; and about 5×10¹⁷ cm⁻³ to about 5×10¹⁸ cm⁻³.

The doping and thickness of the termination p-layer can vary, but optimum values will depend on one another. With a thinner termination layer a higher doping is necessary so that the field can be contained within the layer. An illustrative example of values is a thickness of approximately 0.5 μm with a doping of approximately 1×10¹⁸. Thicknesses of greater than 0.5 μm become more difficult to etch. Therefore, thinner layers are more advantageous. An illustrative range of termination layer thickness is about 0.05 μm to about 2.0 μm, with a preferred range of about 0.1 μm to about 0.5 μm.

The disjointed termination region also differs from a guard ring termination because it may be used for higher voltage designs. Typically, the voltage limit for a guard ring construction is 1000 V. Embodiments of the inventive device can be used for voltages greater than 300 V. It is noted that the epitaxial disjointed p-region can be used in planar termination regions other than the illustrative embodiments described herein.

Preferably the length of the floating p-epilayer is less than 1.5× the n-epilayer thickness. Other illustrative p-epilayer length ranges include 1.25×-1.5× the n-epilayer and 1.2×-1.4× the n-epilayer thickness.

Following is a description of some key advantages to disjointed termination regions as provided by embodiments of the invention:

(1) The disjointed design may reduce termination length for higher voltage devices as compared to JTE and guardrings. Higher dopings allow substantial pinning of electric field lines as compared to JTE. Since JTE requires precise p-type doping, which is usually targeted below the optimum value from practical considerations, it results in a larger termination length for high voltage devices. Higher doping used in embodiments of the present invention will allow substantial reduction in electric fields for smaller termination lengths.

(2) The disjointed edge termination may offer lower leakage current because the leakage current path formed by the p-edge termination region is not continuous, but is physically interrupted. Termination of field lines creates leakage current in the p-type regions if there exists a leakage path to the Anode contact. Since only a small part of the p-edge termination is in contact with the Anode contact, only a small leakage will result as compared to a JTE termination, which has a substantial region to collect the leakage currents.

(3) Embodiments of the present invention may allow a simplified fabrication process as compared to conventional processes because of lack of any p-type implants. Typical edge terminations in SiC Schottky diodes require ion implantation of p-type dopants into the crystal. Such implants cause substantial damage to the crystal lattice, which can be repaired only by annealing at high temperature. This high-temperature anneal step (>1500° C.) is undesirable for a number of reasons. Most importantly, it tends to degrade the surface of SiC on which the Schottky contact is to be made, as silicon tends to dissociate from exposed surfaces of the crystal under such a high-temperature anneal. Loss of silicon in this manner results in a non-ideal Schottky contact between metal and the semiconductor surface. High temperature anneals have other drawbacks as well. Namely, they are typically time-consuming and expensive. Moreover, implantation of p-type (Al) dopants causes substantial lattice damage, or other species (B) have poor activation rates. Finally, they are typically less reproducible as compared to growing the p-layer epitaxially.

(4) Tests comparing the disjointed termination design with a standard JTE show that the disjointed design can provide a more robust design giving better performance and significantly less variation of the performance both in the reverse and forward directions resulting in higher yields.

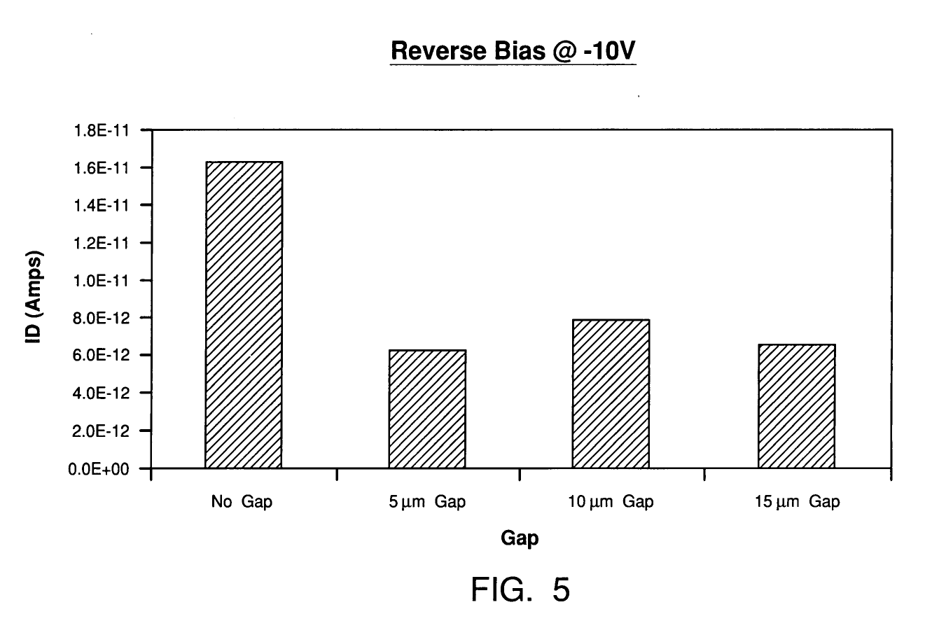

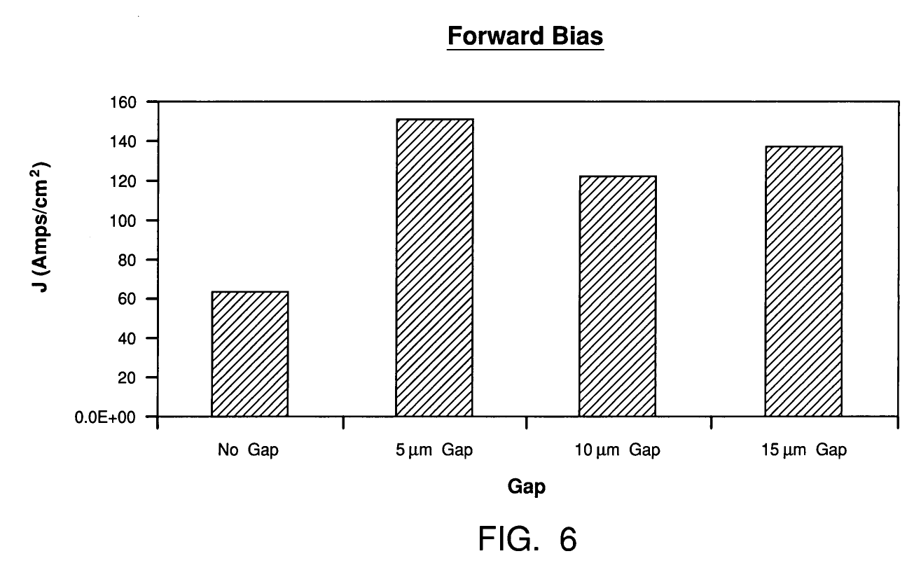

FIG. 5 and FIG. 6 show performance results for devices with disjointed termination regions compared to devices with no gap within the termination region. All devices tested included a circular titanium Schottky region.

FIG. 5 provides results of testing diodes at reverse bias. The leakage current in the reverse direction is greater for diodes having termination regions with no gap as compared to diodes having termination regions with a gap. Gaps of 5 μm, 10 μm and 15 μm all show improved leakage as compared to a continuous termination region surrounding a Schottky region of the same area. A diode having no gap resulted in a leakage current of approximately 1.6×10⁻¹¹ A. Leakage currents for diodes with disjointed termination regions were measured at:

| Gap Width | Approximate Leakage Current (Amps) |
|---|---|
| 5 μm | 6.1 × 10⁻¹² |
| 10 μm | 8.0 × 10⁻¹² |
| 15 μm | 6.3 × 10⁻¹² |

FIG. 6 provides results of testing of diodes at forward bias. The forward current was greater for the diodes having disjointed termination regions as compared to those have continuous termination regions. This result held true for gap widths of 5 μm, 10 μm and 15 μm. The current density for a diode having no gap was measured at approximately 64 amps/cm². Current density for diodes with disjointed termination regions were measured at:

| Gap Width | Approximate Current Density (Amps/cm²) |
|---|---|
| 5 μm | 150 amps/cm² |
| 10 μm | 124 amps/cm² |
| 15 μm | 138 amps/cm² |

Following are the basic steps for fabrication of a device according to an illustrative embodiment of the invention. The layers described may each be formed of one or more layers or materials. Doped layers may be uniform or graded.

(1) First an n-type epitaxial structure with a high doped p-type termination region is formed using an epitaxial growth technique. Preferably both the n-type and the p-type layers are grown in the same epitaxial run. It is noted that the reverse configuration may be used wherein a p-type epitaxial structure with a high doped n-type termination is formed.

(2) A plasma assisted SiO₂ (oxide) is then deposited on the termination layer, and patterned by a photolithographic technique only to be in regions where the termination region is required.

(3) The p-type SiC is then removed where it is not required (where Schottky metal is to be deposited, in the disjoint space, and in the rest of the wafer surface) using reactive ion etch (RIE) or similar.

(4) A thin sacrificial oxide is thermally grown and a photoresist is deposited and hard baked on the front side to protect the Schottky surface. The wafer is dipped in a buffered oxide etch to remove the oxide on the backside. Thereafter the photoresist is removed on the front side.

(5) A suitable ohmic metal, such as Nickel, is deposited on the back side of the device and annealed using a rapid thermal annealing step to form the back side contact. The backside contact is protected with photoresist, which is hard baked.

(6) Thereafter, a buffered oxide etch is used to remove the thermal oxide and using a photolithographic step, Schottky regions are defined and a Schottky metal is deposited. The photoresist is then removed everywhere. The Schottky metal can be any metal with a suitable barrier height to SiC, like Tantalum, Nickel, Chromium, Titanium or Platinum. The Schottky metal may slightly overlap the p-type termination region.

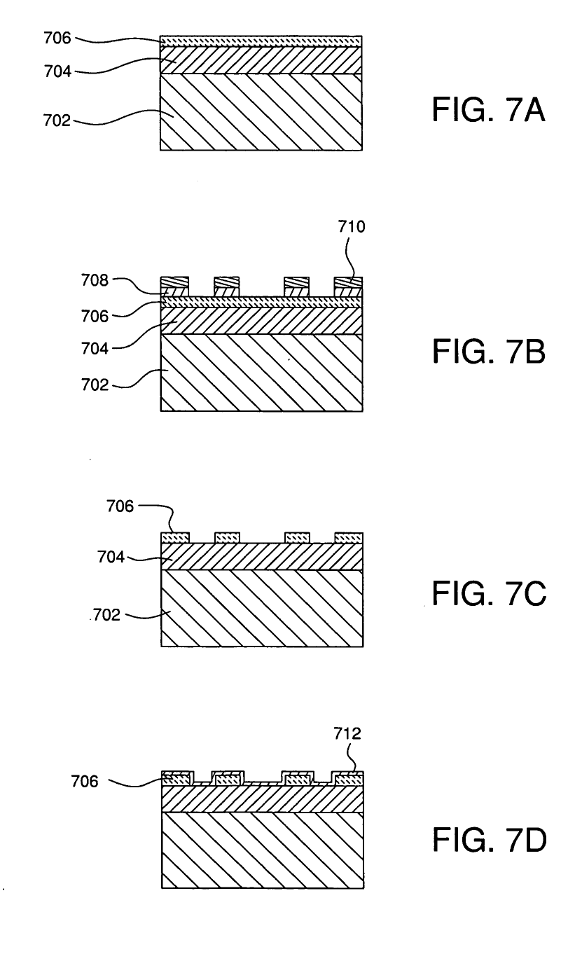

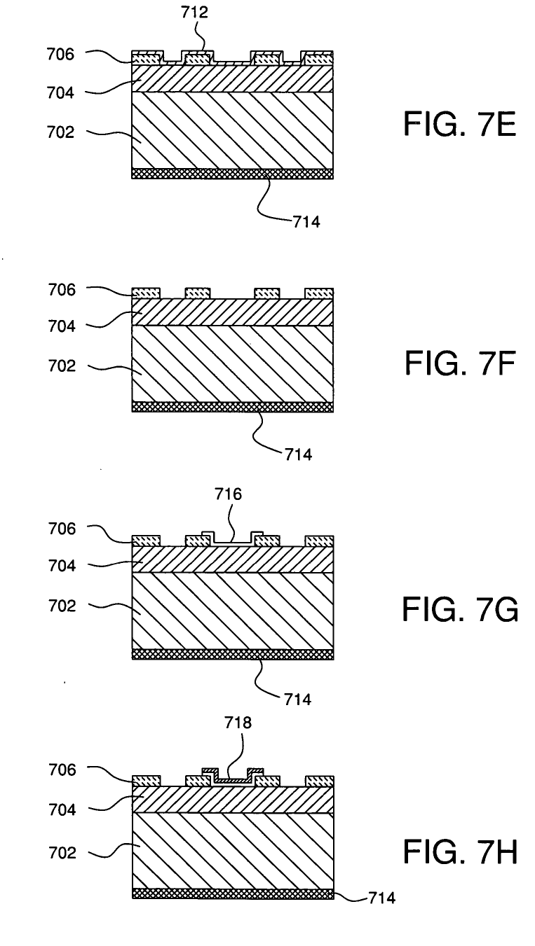

Methods according to illustrative embodiments of the invention will now be described as depicted in FIGS. 7A-H. FIG. 7A depicts the basic layers of the preliminary structure of the device. Substrate 702 is preferably an n⁺-type substrate comprised of SiC. An n⁻ epitaxial blocking layer 704 is provided above substrate 702. Above n− layer 704 is a p+ epitaxial termination layer 706. Although this configuration of n-type and p-type layers is preferred, the reverse configuration is also within the spirit and scope of the invention.

As used herein, “above” means on the front side of the device, such as on the side the Schottky metal region would be located on a Schottky diode. “Below” means on the back side or the side opposite to the front side. When layers are described as “above”, “below” or “on” they need not be immediately adjacent to one another or directly on, however, the order of the layers will be relevant. The terms are used merely as a relative placement indication.

The surface of termination layer 706 preferably undergoes a cleaning process prior to further formation of the device. RCA clean is the standard cleaning for such devices and is an example of a cleaning process that can be used in the inventive processes.

A buffer layer may optionally, but advisably, be positioned between the n-type blocking layer and the n+ substrate.

FIGS. 7B-C depict the termination layer etching stage. An oxide layer 708 is formed on termination layer 706. Oxide layer 708 is preferably formed by plasma enhanced chemical vapor deposition (PECVD). A photoresist is applied to the oxide, preferably at a thickness of 0.05μ. The photoresist is exposed using a patterned mask, and the oxide is etched to the termination layer according to the pattern. Other patterning methods may be used that are compatible with the materials being used.

A nickel layer 710 is then deposited on the patterned oxide layer. (This of course means that the nickel will coat both the oxide layer and the exposed termination layer.) Although Ni is preferred, other metals may be used. Preferably Ni layer 710 is deposited using an e-beam evaporation method to a thickness of approximately 0.1 μm. Ni layer 710 is then patterned, preferably by a lift off process. A typical lift off process would include defining the pattern on oxide layer 708 using a photoresist, blanket-depositing the Ni over oxide layer 708, and lifting-off the Ni according to the pattern by dissolving the photoresist under Ni layer 710. The patterned Ni and oxide layers 708, 710 form a mask by which termination layer 706 can be etched. Preferably an inductively coupled plasma (ICP) etch is used on termination layer 706. Oxide layer 708 and Ni layer 710 can then be removed, for example by dipping in a buffered oxide etch (BOE) and Pirana Solution. The resulting patterned termination layer 706 is shown in FIG. 7C. An RCA clean process can then be used before the next oxide growth portion of the process.

FIGS. 7D depicts an oxide growth step wherein a sacrificial oxide layer 712 is grown on the p⁺type termination layer 706 to protect the front side of the device while a contact is fabricated on the back side of the device. (This of course includes growing or depositing the oxide on the exposed blocking layer, including where the Schottky metal region will be.) Preferably the oxide is thermally grown to a thickness of approximately 0.01μ. Resist is deposited on the front side of the device, preferably by a spin coating method. The photoresist is then hard baked. Oxide that is present on the back side of the device is then etched, such as by dipping it in BOE. The resist can then be removed from the front side of the device, leaving oxide layer 712 on the device's front side.

FIG. 7E depicts the deposition of a contact layer 714 on the back side of the device. An illustrative method of forming contact 714 includes sputter depositing a metal such as nickel, titanium, tantalum, chromium, platinum or other metal with desirable properties. The contact is then rapid thermal annealed at a temperature of approximately 1000° C. in Ar ambient. In an illustrative example, Ti is deposited to a thickness of approximately 0.05μ and Ni is deposited below the Ti to a thickness of approximately 2.5μ.

FIG. 7F depicts the device after oxide layer 712 has been stripped from the device. This may be accomplished by first coating the device with resist on the back side and hard baking it. The device can then be etched, such as by dipping in BOE, to remove the oxide from the device's front side. Finally, the resist is removed from the back side to complete the back side contact formation.

Formation of the Schottky metal region 716 is depicted in FIG. 7G. In a preferred embodiment of the invention, the Schottky metal is deposited by e-beam deposition. Advantageously, titanium or tantalum can be applied to, and performs well, on the C-face of the SiC, even though they have too low a barrier causing significant leakage when used on the Si-face. Ti is the preferred metal for formation of the Schottky metal region 716, however, a variety of metals can be used, alone or in combination. They can be applied to the same SiC face or different faces. An illustrative example of use of two metals to form the Schottky region is as follows: Tantalum is applied by e-beam deposition on the C-face to a thickness of approximately 0.2 μm and Ni is deposited by e-beam deposition on the Si-face to a thickness of about 0.2 μm. The Schottky metal is then patterned, preferably by lift-off. The Schottky metal is rapid thermal annealed at about 550° C. in Ar ambient.

FIG. 7H depicts an optional gold layer 718 on the Schottky metal region 716. Preferably the gold is deposited by e-beam deposition to a thickness of 0.3 μm and patterned by lift-off.

Additional potential benefits of embodiments of the present invention are described as follows:
The surface of the device on which the Schottky contact is formed is not exposed to the ambient during an anneal step. Thus, Si is not lost during the high temperature (>1300° C.) anneal, which results in a more ideal Schottky contact, with lower on-state voltage drop.
A substantial advantage of this processing sequence is that the process is expected to be repeatable within the same wafer and among different wafers.
This technique may allow the achievement of extremely low leakage currents and uniform reverse characteristics because of undamaged termination region and lower temperature processing.

The inventive methods and devices are particularly applicable to Schottky diodes, however, application to other semiconductor devices is within the spirit and scope of the invention.

The invention includes the methods described herein and devices fabricated using the methods. The invention further includes integrated circuits and computer chips incorporating the devices.

While the invention has been described by illustrative embodiments, additional advantages and modifications will occur to those skilled in the art. Therefore, the invention in its broader aspects is not limited to specific details shown and described herein. Modifications, for example, to the metals used and growth and deposition techniques, may be made without departing from the spirit and scope of the invention. Accordingly, it is intended that the invention not be limited to the specific illustrative embodiments, but be interpreted within the full spirit and scope of the appended claims and their equivalents.

Claimed is:

1. A method of forming a semiconductor device comprising:
providing a SiC substrate;
providing a SiC blocking layer above the substrate;
forming a termination layer above the SiC blocking layer;
patterning the termination layer to form a disjointed termination region;
patterning a Schottky metal region; and
depositing metal in the Schottky metal region.

2. The method of claim 1 wherein the termination layer is SiC.

3. The method of claim 1 wherein the termination layer is an epitaxial layer.

4. The method of claim 1 wherein at least a portion of the Schottky metal region is formed on the C-face of the blocking layer.

5. The method of claim 1 wherein:
the substrate is an n-type;
the blocking layer is an n-type; and
the termination layer is a p-type.

6. The method of claim 1 wherein at least a portion of the Schottky metal region is formed from titanium.

7. The method of claim 1 wherein at least a portion of the Schottky region is formed from tantalum.

8. The method of claim 1 wherein at least a portion of the Schottky region is formed from nickel.

9. The method of claim 1 further comprising:
providing a gold layer on the Schottky metal region.

10. The method of claim 1 wherein the termination layer is doped to a level in the range of about 1×10¹⁷ cm−3 to about 1×10²⁰ cm−3.

11. The method of claim 10 wherein the termination layer is doped to a level in the range of about 5×10¹⁷ cm⁻³ to about 5×10¹⁸ cm⁻³.

12. The method of claim 1
wherein the termination layer is patterned using ICP etching.

13. The method of claim 1
wherein the termination layer is patterned using RIE etching.

14. The method of claim 1 comprising rapid thermal annealing the contact after the metal is deposited.

15. The method of claim 1 comprising depositing the Schottky metal region by e-beam deposition.

16. The method of claim 1 comprising patterning the Schottky metal region by lift off.

17. The method of claim 1 comprising rapid thermal annealing the Schottky metal region after it is patterned.

18. The method of claim 1 wherein the thickness of the termination layer is in the range of about 0.05 μm to about 2.0 μm.

19. The method of claim 18 wherein the thickness of the termination layer is in the range of about 0.1 μm to about 0.5 μm.

20. A Schottky diode formed according to claim 1.

21. A semiconductor device comprising:
a SiC substrate;
a SiC blocking layer above the substrate;
a disjointed termination layer above the SiC blocking layer; and
a Schottky metal region.

22. The device of claim 21 wherein:
the substrate is an n-type;
the blocking layer is an n-type; and
the termination layer is a p-type.

23. The device of claim 21 wherein at least a portion of the Schottky metal region is formed from titanium.

24. The device of claim 21 wherein at least a portion of the Schottky metal region is formed from tantalum.

25. The device of claim 21 wherein at least a portion of the Schottky metal region is formed from nickel.

26. The device of claim 21 further comprising:
a gold layer on the Schottky metal region.

27. The device of claim 21 wherein the termination layer has a doping in the range of about 1×10¹⁷ cm⁻³ to about 1×10²⁰ cm⁻³.

28. The device of claim 27 wherein the termination layer has a doping level in the range of about 5×10¹⁷ cm⁻³ to about 5×10¹⁸ cm⁻³.

29. The device of claim 21 wherein the termination layer is SiC.

30. The device of claim 21 wherein the termination layer is an epitaxial layer.

31. The device of claim 21 wherein at least a portion of the Schottky metal region is formed on the C-face of the blocking layer.

32. The device of claim 21 wherein the thickness of the termination layer is in the range of about 0.05 μm to about 2.0 μm.

33. The device of claim 32 wherein the thickness of the termination layer is in the range of about 0.1 μm to about 0.5 μm.
